(19) United States
(12) Patent Application Publication
(10) Pub. No.: US 2020/0407477 A1
(43) Pub. Date: Dec. 31, 2020

(54) POLYMER, POSITIVE RESIST COMPOSITION, AND METHOD OF FORMING RESIST PATTERN

(71) Applicant: ZEON CORPORATION, Chiyoda-ku, Tokyo (JP)

(72) Inventor: Takashi TSUTSUMI, Chiyoda-ku, Tokyo (JP)

(73) Assignee: ZEON CORPORATION, Chiyoda-ku, Tokyo (JP)

(21) Appl. No.: 16/978,187

(22) PCT Filed: Mar. 8, 2019
(86) PCT No.: PCT/JP2019/009504

§ 371 Date: Sep. 4, 2020

(30) Foreign Application Priority Data
Mar. 22, 2018 (JP) 2018-055196

(51) Int. Cl. C08F 220/22; G03F 7/039

(52) U.S. Cl. CPC C08F 220/22; G03F 7/039

(57) ABSTRACT

A polymer includes a monomer unit (A) represented by formula (I), shown below, and a monomer unit (B) represented by formula (II), shown below, and has a weight-average molecular weight of 30,000 or more. In formula (I), B is a bridged saturated hydrocarbon cyclic group that is optionally substituted and n is 0 or 1. In formula (II), R¹ is an alkyl group and p is an integer of not less than 0 and not more than 5, and in a case in which more than one R¹ is present, each R¹ may be the same or different.

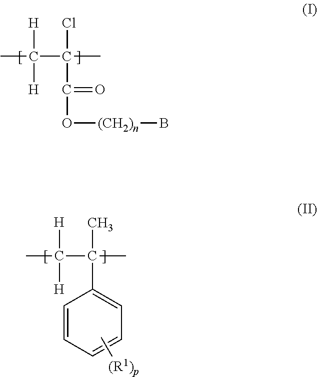

### TECHNICAL FIELD

The present disclosure relates to a polymer, a positive resist composition, and a method of forming a resist pattern, and, in particular, relates to a polymer that can suitably be used as a main chain scission-type positive resist, a positive resist composition that contains the polymer, and a method of forming a resist pattern using the positive resist composition.

### BACKGROUND

Polymers that undergo main chain scission to lower molecular weight upon irradiation with ionizing radiation, such as an electron beam or extreme ultraviolet light (EUV), or short-wavelength light, such as ultraviolet light, are conventionally used as main chain scission-type positive resists in fields such as semiconductor production. (Hereinafter, the term “ionizing radiation or the like” is used to refer collectively to ionizing radiation and short-wavelength light.)

For example, Patent Literature (PTL) 1 reports that a resist pattern having excellent dry etching resistance can be formed using a positive resist formed of an α-methylstyrene-methyl α-chloroacrylate copolymer that includes an α-methylstyrene unit and a methyl α-chloroacrylate unit in a specific ratio.

### CITATION LIST

### Patent Literature

PTL 1: JP-H8-3636B

### SUMMARY

### Technical Problem

However, there has been demand for further increasing dry etching resistance of a resist pattern in the case of the positive resist formed of the α-methylstyrene-methyl α-chloroacrylate copolymer that is described in PTL 1.

Accordingly, one object of the present disclosure is to provide a polymer that can form a resist pattern having excellent dry etching resistance when used as a main chain scission-type positive resist and a positive resist composition that contains this polymer. Another object of the present disclosure is to provide a method of forming a resist pattern that enables formation of a resist pattern having excellent dry etching resistance.

### Solution to Problem

The inventor conducted diligent studies with the aim of achieving the objectives described above. The inventor discovered that by using a polymer formed using specific monomers and having a weight-average molecular weight within a specific range as a main chain scission-type positive resist, it is possible to form a resist pattern having excellent dry etching resistance. In this manner, the inventor completed the present disclosure.

Specifically, the present disclosure aims to advantageously solve the problem set forth above, and a presently disclosed polymer comprises: a monomer unit (A) represented by formula (I), shown below,

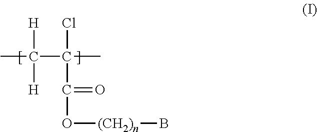

where, in formula (I), B is a bridged saturated hydrocarbon cyclic group that is optionally substituted and n is 0 or 1; and a monomer unit (B) represented by formula (II), shown below,

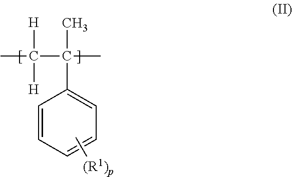

where, in formula (II), R¹ is an alkyl group and p is an integer of not less than 0 and not more than 5, and in a case in which more than one R¹ is present, each R¹ may be the same or different, wherein the polymer has a weight-average molecular weight of 30,000 or more.

By using a polymer that includes the monomer unit (A) and the monomer unit (B) described above and that has a weight-average molecular weight of 30,000 or more, an obtained resist pattern can be caused to display excellent dry etching resistance.

Note that the weight-average molecular weight of a polymer can be measured by a method described in the EXAMPLES section. Also note that the term “optionally substituted” means “unsubstituted or having one or more substituents”.

In the presently disclosed polymer, B is preferably an optionally substituted adamantyl group. A polymer in which B is an optionally substituted adamantyl group has high sensitivity to ionizing radiation or the like. Moreover, a resist pattern can be efficiently formed using this polymer.

Moreover, the present disclosure aims to advantageously solve the problem set forth above, and a presently disclosed positive resist composition comprises: any one of the polymers set forth above; and a solvent. By using a positive resist composition that contains the polymer set forth above, it is possible to form a resist pattern having excellent dry etching resistance.

Furthermore, the present disclosure aims to advantageously solve the problem set forth above, and a presently disclosed method of forming a resist pattern comprises: a step of forming a positive resist film of a main chain scission type using the positive resist composition set forth above; a step of exposing the positive resist film; and a step of developing the positive resist film that has been exposed by bringing the positive resist film into contact with a developer to obtain a developed film, wherein the developer contains a chain dialkyl ether. By using a developer that contains a chain dialkyl ether to develop a positive resist film that has been formed using the positive resist composition set forth above, a resist pattern having excellent dry etching resistance can be favorably formed.

The presently disclosed method of forming a resist pattern preferably further comprises a rinsing step of rinsing the developed film by bringing the developed film into contact with a rinsing liquid after the step of developing, wherein the rinsing liquid contains a hydrocarbon solvent. By using a rinsing liquid that contains a hydrocarbon solvent, a resolution improving effect, an irradiation margin widening effect, and so forth can be obtained in the method of forming a resist pattern.

### Advantageous Effect

According to the present disclosure, it is possible to provide a polymer that can form a resist pattern having excellent dry etching resistance when used as a main chain scission-type positive resist.

Moreover, according to the present disclosure, it is possible to provide a positive resist composition and a method of forming a resist pattern that enable formation of a resist pattern having excellent dry etching resistance.

### DETAILED DESCRIPTION

The following provides a detailed description of embodiments of the present disclosure.

The presently disclosed polymer can be favorably used as a main chain scission-type positive resist that undergoes main chain scission to lower molecular weight upon irradiation with ionizing radiation, such as an electron beam or EUV, or short-wavelength light, such as ultraviolet light. The presently disclosed positive resist composition contains the presently disclosed polymer as a positive resist and can be used, for example, in formation of a resist pattern in a production process of a semiconductor, a photomask, a mold, or the like.

(Polymer)

A feature of the presently disclosed polymer is that it includes: a monomer unit (A) represented by formula (I), shown below,

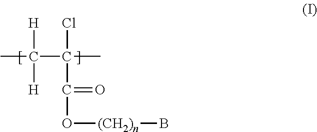

where, in formula (I), B is a bridged saturated hydrocarbon cyclic group that is optionally substituted and n is 0 or 1; and

a monomer unit (B) represented by formula (II), shown below,

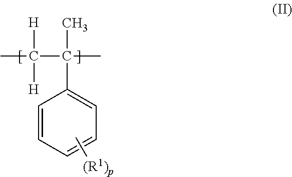

where, in formula (II), R¹ is an alkyl group and p is an integer of not less than 0 and not more than 5, and in a case in which more than one R¹ is present, each R¹ may be the same or different.

Although the presently disclosed polymer may further include any monomer units other than the monomer unit (A) and the monomer unit (B), the total proportion constituted by the monomer unit (A) and the monomer unit (B) among all monomer units included in the polymer is preferably 90 mol % or more, and more preferably 100 mol % (i.e., the polymer more preferably only includes the monomer unit (A) and the monomer unit (B)).

As a result of the presently disclosed polymer including these specific monomer units (A) and (B), the presently disclosed polymer undergoes main chain scission to lower molecular weight upon irradiation with ionizing radiation or the like (for example, an electron beam, KrF laser, ArF laser, or EUV laser). The presently disclosed polymer includes a bridged saturated hydrocarbon cyclic group in the monomer unit (A). A polymer including such a bridged saturated hydrocarbon cyclic group is resistant to decomposition caused by ions, fast neutral particles, radicals, or the like used in dry etching. This is presumed to be due to the contribution of the bulky and rigid structure of the bridged saturated hydrocarbon ring. Therefore, a resist pattern having excellent dry etching resistance can be favorably formed by using the presently disclosed polymer as a main chain scission-type positive resist.

<Monomer Unit (A)>

The monomer unit (A) is a structural unit that is derived from a monomer (a) represented by formula (III), shown below.

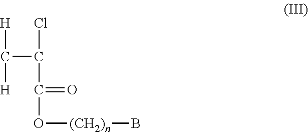

[In formula (III), B and n are the same as in formula (I).]

Although no specific limitations are placed on the proportion constituted by the monomer unit (A) among all monomer units included in the polymer, this proportion may, for example, be not less than 30 mol % and not more than 70 mol %.

The “bridged saturated hydrocarbon cyclic group” that can constitute B in formulae (I) and (III) is a group having a ring structure including at least one bridging group that links two or more non-adjacent atoms in a saturated hydrocarbon ring having the highest carbon number among rings in the group (i.e., the largest saturated hydrocarbon ring).

The largest saturated hydrocarbon ring may, for example, be cyclohexane or cyclooctane.

The bridging group linking two or more non-adjacent atoms in the largest saturated hydrocarbon ring may be any divalent group without any specific limitations, but is preferably an alkylene group, and more preferably a methylene group.

Specific examples of the bridged saturated hydrocarbon cyclic group include an adamantyl group and a norbornyl group. The bridged saturated hydrocarbon cyclic group is preferably an adamantyl group from a viewpoint of improving sensitivity of the polymer to ionizing radiation or the like.

The bridged saturated hydrocarbon cyclic group that can constitute B in formulae (I) and (III) is optionally substituted. Examples of possible substituents of the bridged saturated hydrocarbon cyclic group include, but are not specifically limited to, alkyl groups such as a methyl group and an ethyl group, and a hydroxy group. In a case in which the bridged saturated hydrocarbon cyclic group has more than one substituent, these substituents may be the same or different. Moreover, in a case in which the bridged saturated hydrocarbon cyclic group has more than one substituent, two substituents may be bonded such as to form a heterocycle such as a lactone ring (for example, a γ-butyrolactone ring) or a lactam ring.

From a viewpoint of improving sensitivity of the polymer to ionizing radiation or the like while also raising the glass-transition temperature of the polymer and improving heat resistance of a resist pattern, it is preferable that n in formulae (I) and (III) is 0.

Examples of the monomer (a) represented by the previously described formula (III) that can form the monomer unit (A) represented by the previously described formula (I) include, but are not specifically limited to, α-chloroacrylic acid esters including a bridged saturated hydrocarbon cyclic group such as (a-1) to (a-14), shown below. Of these α-chloroacrylic acid esters, (a-1) to (a-3) and (a-9) to (a-14), which each include an adamantyl group as a bridged saturated hydrocarbon cyclic group, are preferable.

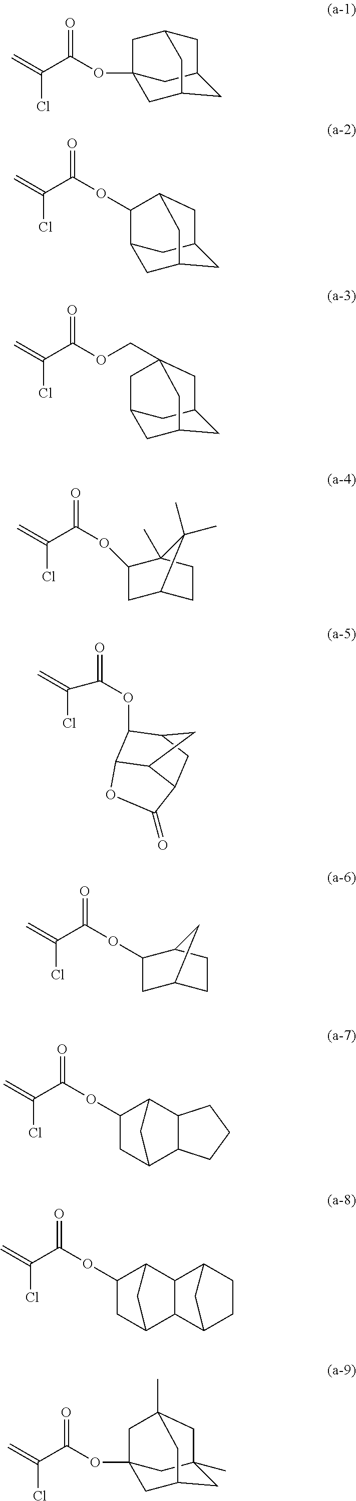

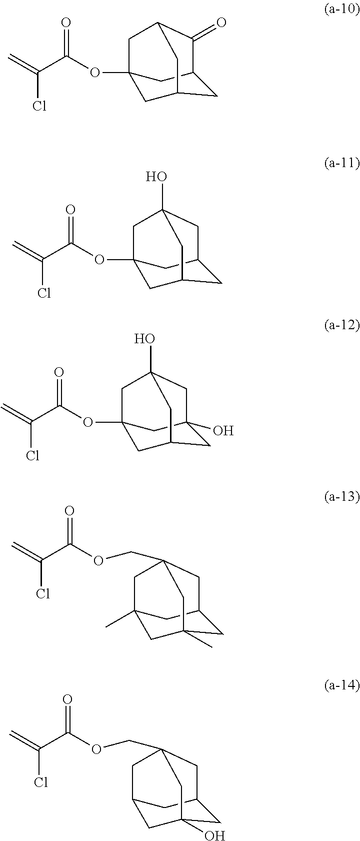 [SMILES: C=C(Cl)C(=O)OC12CC3CC(C1)C(=O)C(C3)C2 ; C=C(Cl)C(=O)OC12CC3CC(CC(O)(C3)C1)C2 ; C=C(Cl)C(=O)OC12CC3CC(O)(CC(O)(C3)C1)C2 ; C=C(Cl)C(=O)OCC12CC3CC(C)(CC(C)(C3)C1)C2 ; C=C(Cl)C(=O)OCC12CC3CC(CC(O)(C3)C1)C2]

<Monomer Unit (B)>

The monomer unit (B) is a structural unit that is derived from a monomer (b) represented by formula (IV), shown below.

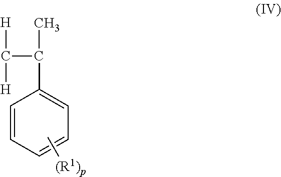

### [In Formula (IV), 10 and p are the Same as in Formula (II).]

Although no specific limitations are placed on the proportion constituted by the monomer unit (B) among all monomer units included in the polymer, this proportion may, for example, be not less than 30 mol % and not more than 70 mol %.

Examples of alkyl groups that can constitute 10 in formulae (II) and (IV) include, but are not specifically limited to, unsubstituted alkyl groups having a carbon number of 1 to 5. Of such alkyl groups, a methyl group or an ethyl group is preferable as an alkyl group that can constitute R′.

From viewpoints of ease of production of the polymer and improving sensitivity of the polymer to ionizing radiation or the like, it is preferable that p in formulae (II) and (IV) is 0. In other words, the monomer unit (B) is preferably a structural unit that is derived from α-methylstyrene (i.e., an α-methylstyrene unit).

—Weight-Average Molecular Weight of Polymer—

The weight-average molecular weight of the polymer is required to be 30,000 or more, is preferably 50,000 or more, and more preferably 60,000 or more, and is preferably 200,000 or less, more preferably 150,000 or less, and even more preferably 120,000 or less. When the weight-average molecular weight of the polymer is 30,000 or more, a resist pattern having excellent dry etching resistance can be favorably formed. Moreover, when the weight-average molecular weight of the polymer is not more than any of the upper limits set forth above, significant reduction of sensitivity in formation of a resist pattern can be inhibited.

—Molecular Weight Distribution of Polymer—

The molecular weight distribution of the polymer (value obtained by dividing the weight-average molecular weight of the polymer by the number-average molecular weight of the polymer) is preferably 2.50 or less, and is preferably 1.05 or more. When the molecular weight distribution of the polymer is not more than the upper limit set forth above, the clarity of a pattern obtained through a method of forming a resist pattern can be increased. Moreover, when the molecular weight distribution of the polymer is not less than the lower limit set forth above, the polymer is easier to produce.

Note that the weight-average molecular weight and the number-average molecular weight of a polymer can be measured by a method described in the EXAMPLES section.

(Production Method of Polymer)

The polymer including the monomer unit (A) and the monomer unit (B) set forth above can be produced, for example, by carrying out polymerization of a monomer composition that contains the monomer (a) and the monomer (b), and then optionally purifying the obtained polymerized product.

<Polymerization of Monomer Composition>

The monomer composition used in production of the presently disclosed polymer may be a mixture containing a monomer component that includes the monomer (a) and the monomer (b), an optional solvent, a polymerization initiator, and optionally added additives. Polymerization of the monomer composition may be carried out by a known method. In particular, the use of cyclopentanone or the like as the solvent is preferable, and the use of a radical polymerization initiator such as azobisisobutyronitrile or dimethyl 2,2′-azobis(2-methylpropionate) as the polymerization initiator is preferable.

A polymerized product obtained through polymerization of the monomer composition may, without any specific limitations, be collected by adding a good solvent such as tetrahydrofuran to a solution containing the polymerized product and subsequently dripping the solution to which the good solvent has been added into a poor solvent such as methanol to coagulate the polymerized product.

<Purification of Polymerized Product>

The method of purification in a case in which the obtained polymerized product is purified may be, but is not specifically limited to, a known purification method such as re-precipitation or column chromatography. Of these purification methods, purification by re-precipitation is preferable.

Note that purification of the polymerized product may be performed repeatedly.

Purification of the polymerized product by re-precipitation is, for example, preferably carried out by dissolving the obtained polymerized product in a good solvent such as tetrahydrofuran, and subsequently adding the resultant solution dropwise to a mixed solvent of a good solvent, such as tetrahydrofuran, and a poor solvent, such as methanol, to cause precipitation of a portion of the polymerized product.

Also note that in a situation in which the polymerized product is purified by re-precipitation, polymerized product that precipitates in the mixed solvent of the good solvent and the poor solvent may be used as the presently disclosed polymer, or polymerized product that does not precipitate in the mixed solvent (i.e., polymerized product dissolved in the mixed solvent) may be used as the presently disclosed polymer. Polymerized product that does not precipitate in the mixed solvent can be collected from the mixed solvent by a known technique such as concentration to dryness.

(Positive Resist Composition)

The presently disclosed positive resist composition contains the polymer set forth above and a solvent, and may optionally further contain known additives that can be contained in resist compositions. As a result of the presently disclosed positive resist composition containing the polymer set forth above as a positive resist, the presently disclosed positive resist composition can be used to form a resist pattern having excellent dry etching resistance.

<Solvent>

The solvent may be any solvent in which the polymer set forth above is soluble without any specific limitations. For example, known solvents such as those described in JP5938536B can be used. Of such solvents, anisole, propylene glycol monomethyl ether acetate (PGMEA), cyclopentanone, cyclohexanone, or methyl 3-methoxypropionate is preferable as the solvent from a viewpoint of obtaining a positive resist composition of suitable viscosity and improving coatability of the positive resist composition.

(Method of Forming Resist Pattern)

The presently disclosed method of forming a resist pattern uses the presently disclosed positive resist composition set forth above. Specifically, the presently disclosed method of forming a resist pattern includes a step of forming a positive resist film of a main chain scission type using the presently disclosed positive resist composition (resist film formation step), a step of exposing the positive resist film (exposure step), and a step of developing the positive resist film that has been exposed by bringing the positive resist film into contact with a developer to obtain a developed film (development step). In the presently disclosed method of forming a resist pattern, a developer that contains a chain dialkyl ether is used as the developer in the development step. By using a chain dialkyl ether to develop a positive resist film that has been formed using the presently disclosed positive resist composition containing the specific polymer described above, it is possible to form a resist pattern having excellent dry etching resistance. The use of a developer that contains a chain dialkyl ether as a developer for a positive resist film that has been formed using the presently disclosed positive resist composition containing the specific polymer described above has benefits such as described below. These benefits include 1) dissolution of a region of the positive resist film that has not been irradiated with ionizing radiation or the like (non-irradiated region) can be inhibited and undesirable change of thickness of the non-irradiated region can be inhibited (hereinafter, also referred to as a “thickness change inhibiting effect”); 2) sensitivity and resolution in the method of forming a resist pattern can be increased; and 3) an applicable range for the irradiation dose of ionizing radiation or the like in the exposure step of the method of forming a resist pattern can be made comparatively wide (hereinafter, also referred to as an “irradiation margin widening effect”).

A rinsing step of rinsing the developed film by bringing the developed film into contact with a rinsing liquid may optionally be implemented after the development step.

The following describes each of the steps.

<Resist Film Formation Step>

In the resist film formation step, the positive resist composition is applied onto a workpiece, such as a substrate, that is to be processed using a resist pattern, and the applied positive resist composition is dried to form a resist film. The substrate is not specifically limited and may be a silicon substrate or the like used in a semiconductor device such an LSI (Large Scale Integration) semiconductor device or a mask blank including a light shielding layer formed on a substrate.

Moreover, no specific limitations are placed on the application method and the drying method of the positive resist composition, and any method that is typically used in formation of a resist film may be adopted. For example, the resist solution may be applied onto a substrate by spin coating and then a softbake may be performed on a hot-plate to form a resist film. The temperature of the softbake is not specifically limited and can be set as not lower than 100° C. and not higher than 200° C. Moreover, the softbake time can be set as not less than 30 seconds and not more than 60 minutes, for example. Note that the previously described positive resist composition is used in the presently disclosed method of forming a resist pattern.

<Exposure Step>

In the exposure step, the positive resist film that has been formed in the resist film formation step is irradiated with ionizing radiation or light to write a desired pattern.

Irradiation with ionizing radiation or light can be carried out using a known writing device such as an electron beam writer or a laser writer.

<Development step>

In the development step, the resist film that has been exposed in the exposure step and a developer are brought into contact to develop the resist film and form a resist pattern on the workpiece.

The method by which the resist film and the developer are brought into contact may be, but is not specifically limited to, a method using a known technique such as immersion of the resist film in the developer or application of the developer onto the resist film. The temperature of the developer is not specifically limited and can, for example, be not lower than −20° C. and not higher than 25° C. Moreover, the development time can, for example, be not less than 30 seconds and not more than 10 minutes.

[Developer]

The developer used in the presently disclosed method of forming a resist pattern is required to contain a chain dialkyl ether. The chain dialkyl ether is a non-cyclic aliphatic ether having a structure in which two linear or branched alkyl groups are linked through an ether bond. The two linear or branched alkyl groups may be the same or different, but are preferably the same. More specifically, the chain dialkyl ether may be a linear alkyl group-containing ether such as di-n-propyl ether, di-n-butyl ether (hereinafter, also referred to as “dibutyl ether”), di-n-pentyl ether (hereinafter, also referred to as “diamyl ether”), or di-n-hexyl ether (hereinafter, also referred to as “dihexyl ether”); or a branched alkyl group-containing ether such as diisohexyl ether, methyl isopentyl ether, ethyl isopentyl ether, propyl isopentyl ether, diisopentyl ether (hereinafter, also referred to as “diisoamyl ether”), methyl isobutyl ether, ethyl isobutyl ether, propyl isobutyl ether, diisobutyl ether, diisopropyl ether, ethyl isopropyl ether, or methyl isopropyl ether. One of these chain dialkyl ethers may be used individually, or two or more of these chain dialkyl ethers may be used in combination. Of these chain dialkyl ethers, those in which the two linear or branched alkyl groups that are linked through the ether bond each have a carbon number of 3 to 7 are preferable from a viewpoint of increasing the previously described thickness change inhibiting effect and irradiation margin widening effect, and improving sensitivity and resolution, and those in which the two linear or branched alkyl groups each have a carbon number of 5 or 6 are more preferable. Of such chain dialkyl ethers, diamyl ether, diisoamyl ether, and dihexyl ether are preferable, and diisoamyl ether is particularly preferable. Note that in addition to a chain dialkyl ether such as described above, the developer may optionally further contain additives that are commonly known as surfactants and antioxidants. In a case in which the developer contains an optional component, the concentration of the optional component in the developer may be 2 mass % or less, for example.

<Rinsing Step>

In the optionally performed rinsing step, the resist film that has been developed in the development step and a specific rinsing liquid are brought into contact to rinse the developed resist film and form a resist pattern on the workpiece. A rinsing liquid that contains a hydrocarbon solvent can suitably be used as the rinsing liquid.

[Rinsing Liquid]

Examples of suitable hydrocarbon solvents that can be contained in the rinsing liquid include linear and branched aliphatic hydrocarbons having a carbon number of 12 or less. Specifically, the hydrocarbon solvent contained in the rinsing liquid may be a linear alkane such as n-heptane, n-nonane, or n-decane or a branched alkane such as isopentane, isohexane, or isooctane, and is preferably a linear alkane. One of these hydrocarbon solvents may be used individually, or two or more of these hydrocarbon solvents may be used in combination. By using a hydrocarbon solvent as the rinsing liquid, pattern collapse can be effectively inhibited in the rinsing step, and, as a result, it is possible achieve the effect of improving resolution and the irradiation margin widening effect in the method of forming a resist pattern. Note that in addition to a hydrocarbon solvent such as described above, the rinsing liquid may optionally further contain additives commonly known as surfactants and like. In a case in which the rinsing liquid contains an optional component, the concentration of the optional component in the rinsing liquid may be 2 mass % or less, for example.

The temperature of the rinsing liquid in the rinsing step is not specifically limited and can, for example, be not lower than −20° C. and not higher than 25° C. More, the rinsing time can, for example, be not less than 5 seconds and not more than 3 minutes.

### EXAMPLES

The following provides a more specific description of the present disclosure based on examples. However, the present disclosure is not limited to the following examples. In the following description, “%” and “parts” used in expressing quantities are by mass, unless otherwise specified.

In the examples and comparative examples, the following methods were used to measure and evaluate the weight-average molecular weight and molecular weight distribution of a polymer, the dry etching resistance of a resist pattern, the thickness change of a resist film, and the sensitivity, resolution, and irradiation margin in a method of forming a resist pattern.

<Molecular Weight and Molecular Weight Distribution>

The weight-average molecular weight (Mw) and number-average molecular weight of an obtained polymer were each determined as a value in terms of standard polystyrene using a gel permeation chromatograph (HLC-8220 produced by Tosoh Corporation) in which a TSKgel G4000HXL, a TSKgel G2000HXL, and a TSKgel G1000HXL (each produced by Tosoh Corporation) were linked as a column and using tetrahydrofuran as a eluent solvent. A value for the molecular weight distribution (Mw/Mn) was then calculated from the values determined for the weight-average molecular weight (Mw) and the number-average molecular weight (Mn).

<Dry Etching Resistance of Resist Film>

A polymer produced in each example or comparative example was dissolved in anisole and was then filtered using a polyethylene filter having a pore size of 0.25 μm to obtain a positive resist composition (polymer concentration: 2.5 mass %). The obtained positive resist composition was applied onto a silicon wafer of 4 inches in diameter by a spin coater and was subsequently heated for 3 minutes by a hot-plate at a temperature of 180° C. to form a resist film of 150 nm in thickness. The thickness T0 (nm) of the resist film was measured. Next, the silicon wafer including the resist film was introduced into a sputtering apparatus and was subjected to 1 minute of reverse sputtering with oxygen plasma. The thickness T1 (nm) of the resist film after reverse sputtering was measured. The film loss rate (=T0−T1 [film loss per 1 minute; units: nm/min]) was calculated and dry etching resistance was evaluated in accordance with the following standard. A smaller value for the film loss rate indicates higher dry etching resistance. Moreover, when a resist film has high dry etching resistance, this means that a resist pattern formed using the resist film will have high dry etching resistance.

A: Film loss rate of less than 27 nm/min

B: Film loss rate of not less than 27 nm/min and less than 30 nm/min

C: Film loss rate of 30 nm/min or more

<Thickness Change of Resist Film>

A polymer produced in each example or comparative example was dissolved in anisole and was then filtered using a polyethylene filter having a pore size of 0.25 μm to obtain a positive resist composition (polymer concentration: 2.5 mass %). A spin coater (MS-A150 produced by Mikasa Co., Ltd.) was used to apply the positive resist composition onto a silicon wafer of 4 inches in diameter such as to have a thickness of 100 nm. The applied positive resist composition was heated for 3 minutes by a hot-plate at a temperature of 180° C. to form a resist film on the silicon wafer.

The silicon wafer on which the resist film had been formed was immersed in a developer for 3 minutes at 23° C., was subsequently rinsed with isopropanol for 10 seconds, and was then dried by blowing with nitrogen gas. The film thickness before and after immersion in the developer was measured by a spectroscopic film thickness measurement tool (Lambda Ace VM-1210 produced by SCREEN Semiconductor Solutions Co., Ltd.), and the rate of thickness change was calculated by the following formula.

Rate of thickness change (%)=|Film thickness before immersion in developer (nm)−Film thickness after immersion in developer (nm)|/Film thickness before immersion in developer (nm)×100

The value calculated for the rate of thickness change was evaluated in accordance with the following standard.

A: Less than 1%

B: Not less than 1% and less than 5%

C: Not less than 5% and less than 10%

D: 10% or more

<Sensitivity>

A polymer produced in each example or comparative example was dissolved in anisole and was then filtered using a polyethylene filter having a pore size of 0.25 μm to obtain a positive resist composition (polymer concentration: 1.5 mass %). A spin coater (MS-A150 produced by Mikasa Co., Ltd.) was used to apply the positive resist composition onto a silicon wafer of 4 inches in diameter such as to have a thickness of 40 nm. The applied positive resist composition was heated for 3 minutes by a hot-plate at a temperature of 180° C. to form a resist film on the silicon wafer. An electron beam lithography tool (ELS-5700 produced by Elionix Inc.) was used to write a square pattern of 500 μm×500 μm at 50 locations in total at an accelerating voltage of 50 KV and an irradiation dose that was increased up to 300 μC/cm² in increments of 6 μC/cm².

The wafer including the resist film that had undergone electron beam writing was treated with a developer for 1 minute and a rinsing liquid for 10 seconds at 23° C. A spectroscopic film thickness measurement tool (Lambda Ace VM-1210 produced by SCREEN Semiconductor Solutions Co., Ltd.) was used to measure the film thickness of written pattern sections, and a relationship of film thickness to irradiation dose (contrast curve) was determined. A section of the contrast curve corresponding to a normalized film thickness of 0.8 to 0.2 was approximated by a quadratic function, the irradiation dose at an intersection point of the approximation with the X axis was taken to be the resist sensitivity, and the resist sensitivity was evaluated by the following standard.

A: Less than 150 μC/cm²

B: Not less than 150 μC/cm² and less than 200 μC/cm²

C: 200 μC/cm² or more

<Resolution>

A polymer produced in each example or comparative example was dissolved in anisole and was then filtered using a polyethylene filter having a pore size of 0.25 μm to obtain a positive resist composition (polymer concentration: 1.5 mass %). A spin coater (MS-A150 produced by Mikasa Co., Ltd.) was used to apply the positive resist composition onto a silicon wafer of 4 inches in diameter such as to have a thickness of 40 nm. The applied positive resist composition was heated for 3 minutes by a hot-plate at a temperature of 180° C. to form a positive resist film on the silicon wafer. An electron beam lithography tool (ELS-5700 produced by Elionix Inc.) was used to perform electron beam writing of a line-and-space 1:1 pattern having a line width of 18 nm, 20 nm, 22 nm, 24 nm, or 26 nm so as to obtain a wafer that had undergone electron beam writing. Note that in the electron beam writing, a plurality of irradiation regions for which the irradiation dose was varied in an irradiation dose range of 100 μC/cm² to 400 μC/cm² in increments of 10 μC/cm² was set for each of the patterns.

Each wafer that had undergone electron beam writing was immersed in a developer for 1 minute and in a rinsing liquid for 10 seconds at 23° C. to form a line-and-space pattern. The resolution in the method of forming a resist pattern was evaluated by the following standard in accordance with the smallest line-and-space width for which there was separated resolution of the pattern as observed at ×50,000 magnification using a scanning electron microscope (SEM). Note that in this evaluation, a plurality of irradiation regions having different electron beam irradiation doses were set for a line-and-space pattern of a given line width as previously described. When a wafer that had undergone electron beam writing with a line-and-space pattern of a certain line width was developed and rinsed, so long as a pattern with separated resolution was obtained in at least one of the irradiation regions, separated resolution was judged to be possible for a line-and-space pattern of that line width. The smallest line width among line widths for which separated resolution was possible was taken to be the “smallest line-and-space width for which there was separated resolution of the pattern”.

A: 18 nm to 20 nm

B: 22 nm to 26 nm

C: Pattern not resolved at any line width

<Irradiation Margin>

A polymer produced in each example or comparative example was dissolved in anisole and was then filtered using a polyethylene filter having a pore size of 0.25 μm to obtain a positive resist composition (polymer concentration: 1.5 mass %). A spin coater (MS-A150 produced by Mikasa Co., Ltd.) was used to apply the positive resist composition onto a silicon wafer of 4 inches in diameter such as to have a thickness of 40 nm. The applied positive resist composition was heated for 3 minutes by a hot-plate at a temperature of 180° C. to form a positive resist film on the silicon wafer. An electron beam lithography tool (ELS-5700 produced by Elionix Inc.) was used to perform electron beam writing of a line-and-space 1:1 pattern having a line width of 26 nm with an electron beam irradiation dose that was varied from 100 μC/cm² to 400 μC/cm² in increments of 10 μC/cm². Note that a plurality of irradiation regions having different electron beam irradiation doses were set in the same manner as in evaluation of “Resolution” described above.

The wafer that had undergone electron beam writing was immersed in a developer for 1 minute and in a rinsing liquid for 10 seconds at 23° C. to form a line-and-space pattern. The number of irradiation regions for which there was line and space separation and in which pattern collapse and sticking together did not occur was counted through SEM observation at ×50,000 magnification, and was evaluated by the following standard.

A: 8 or more regions

B: 4 to 7 regions

C: 3 or fewer regions

### Example 1

<Synthesis of Monomer (a-1)>

A three-necked flask was charged with 30.0 g of 1-adamantyl acrylate, 300 mL of dehydrated chloroform, and 0.9 mL of dehydrated dimethylformamide in a stream of nitrogen. These materials were stirred and were cooled to 5° C. An internal temperature of 20° C. or lower was maintained while introducing 15.7 g of chlorine gas and carrying out a reaction for 12 hours. The reaction liquid was concentrated under reduced pressure, and then the resultant crude product was purified by column chromatography (eluent solvent: heptane/chloroform=10/1 (volume ratio)) and was concentrated under reduced pressure. Next, 200 mL of hexane was added to the concentrate and cooling thereof was performed to 0° C. Thereafter, 50 g of triethylamine was slowly added dropwise, the temperature was raised to room temperature, and a reaction was carried out for 5 hours. Precipitated salt was filtrated off using a Kiriyama funnel and was washed twice with 50 mL of hexane. The filtrate and washings were subjected to a liquid separation operation twice using 1 M hydrochloric acid, twice using saturated sodium hydrogen carbonate aqueous solution, and twice using saturated saline water. Anhydrous magnesium sulfate was added to the organic layer and then the organic layer was filtered, and the filtrate was concentrated under reduced pressure. The concentrate was purified by column chromatography (eluent solvent: hexane/ethyl acetate=40/1 (volume ratio)) and was concentrated to obtain a monomer (a-1) having the structure in the following formula.

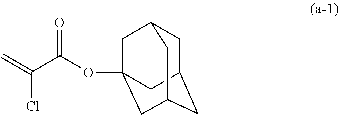 [SMILES: C=C(Cl)C(=O)OC12CC3CC(CC(C3)C1)C2]

<Synthesis of Polymer 1>

A glass ampoule in which a stirrer had been placed was charged with 40.00 g of the monomer (a-1), 46.03 g of α-methylstyrene as a monomer (b), 0.055 g of azobisisobutyronitrile as a polymerization initiator, and 21.50 g of cyclopentanone as a solvent and was tightly sealed. Oxygen was removed from the system through 10 repetitions of pressurization and depressurization with nitrogen gas.

The system was then heated to 78° C. and a reaction was carried out for 6 hours. Next, 100 g of tetrahydrofuran was added to the system and then the resultant solution was added dropwise to 2.0 L of methanol to cause precipitation of a polymerized product. Thereafter, the precipitated polymerized product was collected by filtration and was then dissolved in 200 g of tetrahydrofuran. The resultant solution was added dropwise to 2.0 L of methanol. Produced sediment was collected by filtration and was dried at 50° C. for 24 hours under reduced pressure to obtain a polymer 1 including the following two types of monomer units.

The obtained polymer had a weight-average molecular weight (Mw) of 62,000 and a molecular weight distribution (Mw/Mn) of 1.79. The monomer ratio calculated through ¹H-NMR measurement was 46 mol % of α-methylstyrene units and 54 mol % of 1-adamantyl α-chloroacrylate units.

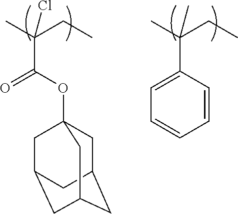

Various evaluations were conducted as previously described. The results are shown in Table 1. Note that in evaluation of thickness change of a resist film, dry etching resistance of a resist film, and sensitivity, resolution, and irradiation margin in a method of forming a resist pattern, diamyl ether as a chain dialkyl ether was used as the developer and n-heptane as a hydrocarbon solvent was used as the rinsing liquid.

### Example 2

Various evaluations were conducted in the same manner as in Example 1 with the exception that diisoamyl ether (containing 2 mass % or less of di-tert-butylhydroxytoluene as an antioxidant) as a chain dialkyl ether was used as the developer and n-nonane as a hydrocarbon solvent was used as the rinsing liquid in the various evaluations. The results are shown in Table 1.

### Example 3

### <Synthesis of Polymer 2>

A polymer 2 was obtained in the same way as in synthesis of the polymer 1 with the exception that the amount of azobisisobutyronitrile used as a polymerization initiator in synthesis of the polymer 1 was changed from 0.055 g to 0.0018 g.

The obtained polymer 2 had a weight-average molecular weight (Mw) of 112,000 and a molecular weight distribution (Mw/Mn) of 2.30. The monomer ratio calculated through ¹H-NMR measurement was 46 mol % of α-methylstyrene units and 54 mol % of 1-adamantyl α-chloroacrylate units.

Various evaluations were conducted as previously described using the polymer 2. The results are shown in Table 1. Note that dihexyl ether as a chain dialkyl ether was used as the developer and n-decane as a hydrocarbon solvent was used as the rinsing liquid in the various evaluations.

### Example 4

### <Production of Polymer 3>

A solution obtained by dissolving 5 g of the polymer 1 in 50 g of tetrahydrofuran (THF) was added dropwise to a mixed solvent of 337 g of THF and 500 g of methanol (MeOH). Thereafter, the solution was filtered using a Kiriyama funnel, insoluble matter was collected, and then the insoluble matter was vacuum dried at 50° C. for 24 hours.

The obtained polymer had a weight-average molecular weight (Mw) of 69,000 and a molecular weight distribution (Mw/Mn) of 1.42. The monomer ratio calculated through ¹H-NMR measurement was 46 mol % of α-methylstyrene units and 54 mol % of 1-adamantyl α-chloroacrylate units.

Various evaluations were conducted as previously described using the polymer 3. The results are shown in Table 1. Note that dihexyl ether as a chain dialkyl ether was used as the developer and n-decane as a hydrocarbon solvent was used as the rinsing liquid in the various evaluations.

### Example 5

<Synthesis of Monomer (a-2)>

A three-necked flask to which a Dean-Stark apparatus had been attached was charged with 56.3 g of 2,3-dichloropropionic acid, 50.0 g of 2-adamantanol, 1.9 g of dimesitylammonium pentafluorobenzenesulfonate, and 200 mL of toluene in a stream of nitrogen. The flask was heated to 120° C. and a reaction was carried out for 24 hours while evaporating produced water.

The reaction liquid was cooled to room temperature, 300 mL of hexane was subsequently added, and then the reaction liquid was further cooled to 0° C. Next, 50 g of triethylamine was slowly added dropwise, the reaction liquid was heated to room temperature, and a reaction was carried out for 5 hours. Precipitated salt was filtered off using a Kiriyama funnel and was washed twice with 50 mL of hexane. The filtrate and washings were subjected to a liquid separation operation twice using 1 M hydrochloric acid, twice using saturated sodium hydrogen carbonate aqueous solution, and twice using saturated saline water. Anhydrous magnesium sulfate was added to the organic layer and then the organic layer was filtered. The filtrate was concentrated in an evaporator. Hexane was added to the concentrate, heating was performed to 60° C., and once dissolution was achieved, cooling was performed to 0° C. to cause precipitation of crystals. The crystals were filtered off using a Kiriyama funnel and were dried under reduced pressure at room temperature for 24 hours to obtain a monomer (a-2) having the structure in the following formula.

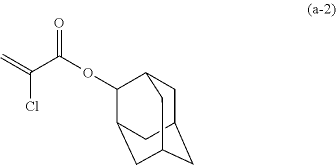 [SMILES: C=C(Cl)C(=O)OC1C2CC3CC(C2)CC1C3]

<Synthesis of Polymer 4>

A glass ampoule in which a stirrer had been placed was charged with 10.00 g of the monomer (a-2), 10.51 g of α-methylstyrene as a monomer (b), 0.019 g of dimethyl 2,2′-azobis(2-methylpropionate) as a polymerization initiator, and 5.38 g of cyclopentanone as a solvent and was tightly sealed. Oxygen was removed from the system through 10 repetitions of pressurization and depressurization with nitrogen gas.

The system was then heated to 78° C. and a reaction was carried out for 6 hours. Next, 20 g of tetrahydrofuran was added to the system and then the resultant solution was added dropwise to 1.5 L of methanol to cause precipitation of a polymerized product. Thereafter, the precipitated polymerized product was collected by filtration and was then dissolved in 20 g of tetrahydrofuran. The resultant solution was added dropwise to 1.5 L of methanol. Produced sediment was collected by filtration and was dried at 50° C. for 24 hours to obtain a polymer 4 including the following two types of monomer units.

The obtained polymer 4 had a weight-average molecular weight (Mw) of 72,000 and a molecular weight distribution (Mw/Mn) of 1.87. The monomer ratio calculated through ¹H-NMR measurement was 46 mol % of α-methylstyrene units and 54 mol % of 2-adamantyl α-chloroacrylate units.

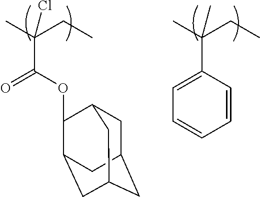

Various evaluations were conducted as previously described using the polymer 4. The results are shown in Table 1. Note that diamyl ether as a chain dialkyl ether was used as the developer and n-decane as a hydrocarbon solvent was used as the rinsing liquid in the various evaluations.

### Example 6

Various evaluations were conducted using a polymer having the same chemical composition as the polymer 4 produced in Example 5. Dihexyl ether as a chain dialkyl ether was used as the developer and n-heptane as a hydrocarbon solvent was used as the rinsing liquid in the various evaluations. The results are shown in Table 1.

### Example 7

Various evaluations were conducted using a polymer having the same chemical composition as the polymer 4 produced in Example 5. Dibutyl ether (containing 2 mass % or less of di-tert-butylhydroxytoluene as an antioxidant) as a chain dialkyl ether was used as the developer and n-decane as a hydrocarbon solvent was used as the rinsing liquid in the various evaluations. The results are shown in Table 1.

### Example 8

<Synthesis of Monomer (a-3)>

A three-necked flask to which a Dean-Stark apparatus had been attached was charged with 25.3 g of 2,3-dichloropropionic acid, 24.5 g of 1-adamantanemethanol, 0.7 g of dimesitylammonium pentafluorobenzenesulfonate, and 100 mL of toluene in a stream of nitrogen. Thereafter, the flask was heated and a reaction was carried out for 16 hours, with 12 hours at 80° C. and 4 hours at 130° C., while evaporating produced water.

The reaction liquid was cooled to room temperature, 150 mL of hexane was subsequently added, and then the reaction liquid was further cooled to 0° C. Next, 22.5 g of triethylamine was slowly added dropwise, the reaction liquid was heated to room temperature, and a reaction was carried out for 5 hours. Precipitated salt was filtered off using a Kiriyama funnel and was washed twice with 25 mL of hexane. The filtrate and washings were subjected to a liquid separation operation twice using 1 M hydrochloric acid, twice using saturated sodium hydrogen carbonate aqueous solution, and twice using saturated saline water. Anhydrous magnesium sulfate was added to the organic layer and then the organic layer was filtered. The filtrate was concentrated in an evaporator. A small amount of hexane was added to the concentrate, filtration was performed using a Kiriyama funnel, and then drying under reduced pressure was performed for 24 hours at room temperature to obtain a monomer (a-3) having the structure in the following formula.

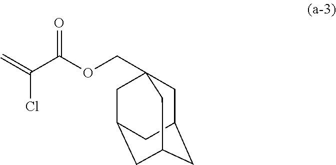 [SMILES: C=C(Cl)C(=O)OCC12CC3CC(CC(C3)C1)C2]

<Synthesis of Polymer 5>

A glass ampoule in which a stirrer had been placed was charged with 10.00 g of the monomer (a-3), 10.86 g of α-methylstyrene as a monomer (b), 0.015 g of azobisisobutyronitrile as a polymerization initiator, and 2.60 g of cyclopentanone as a solvent and was tightly sealed. Oxygen was removed from the system through 10 repetitions of pressurization and depressurization with nitrogen gas.

The system was then heated to 78° C. and a reaction was carried out for 6 hours. Next, 20 g of tetrahydrofuran was added to the system and then the resultant solution was added dropwise to 1.0 L of methanol to cause precipitation of a polymerized product. Thereafter, the precipitated polymerized product was collected by filtration and was then dissolved in 20 g of tetrahydrofuran. The resultant solution was added dropwise to 1.0 L of methanol. Produced sediment was collected by filtration and was dried at 50° C. for 24 hours to obtain a polymer 5 including the following two types of monomer units.

The obtained polymer 5 had a weight-average molecular weight (Mw) of 58,000 and a molecular weight distribution (Mw/Mn) of 1.78. The monomer ratio calculated through ¹H-NMR measurement was 46 mol % of α-methylstyrene units and 54 mol % of methyl-1-adamantyl α-chloroacrylate units.

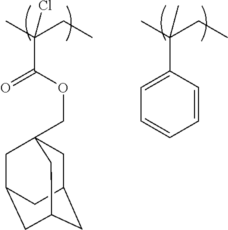

Various evaluations were conducted as previously described using the polymer 5. The results are shown in Table 1. Note that diisoamyl ether (containing 2 mass % or less of di-tert-butylhydroxytoluene as an antioxidant) as a chain dialkyl ether was used as the developer and n-decane as a hydrocarbon solvent was used as the rinsing liquid in the various evaluations.

### Example 9

Various evaluations were conducted using a polymer having the same chemical composition as the polymer 1 produced in Example 1. The results are shown in Table 1. Note that cyclopentyl methyl ether (containing 0.5 mass % or less of di-tert-butylhydroxytoluene as an antioxidant) was used as the developer and n-decane was used as the rinsing liquid in the various evaluations.

Although the evaluation result for dry etching resistance of a resist film was good in the same way as in Example 1, the resist film dissolved excessively in the developer because cyclopentyl methyl ether, which is a cyclic alkyl ether, was used as the developer. Consequently, a D evaluation was given for thickness change of the resist film, and other evaluations in which an exposure step was performed could not be conducted because the film was lost through dissolution in the developer.

### Comparative Example 1

### <Synthesis of Polymer 6>

A polymer 6 was obtained in the same way as in synthesis of the polymer 1 with the exception that the amount of azobisisobutyronitrile used as a polymerization initiator was changed from 0.055 g to 0.912 g.

The obtained polymer had a weight-average molecular weight (Mw) of 15,000 and a molecular weight distribution (Mw/Mn) of 1.67. The monomer ratio calculated through ¹H-NMR measurement was 46 mol % of α-methylstyrene units and 54 mol % of 1-adamantyl α-chloroacrylate units.

Various evaluations were conducted as previously described using the polymer 6. The results are shown in Table 1. Note that diisoamyl ether (containing 2 mass % or less of di-tert-butylhydroxytoluene as an antioxidant) was used as the developer and n-heptane was used as the rinsing liquid in the various evaluations.

Although the low molecular weight polymer 6 had high sensitivity, it had poor dry etching resistance and resistance to resist film thickness change. Moreover, a method of forming a resist pattern using the polymer 6 had poorer results than the examples in terms of resolution and irradiation margin.

### Comparative Example 2

### <Synthesis of Polymer 7>

A glass vessel was charged with a monomer composition containing 3.0 g of methyl α-chloroacrylate and 6.88 g of α-methylstyrene as monomers, 12.1 g of cyclopentanone as a solvent, and 0.012 g of azobisisobutyronitrile as a polymerization initiator. The glass vessel was tightly sealed and was purged with nitrogen. The glass vessel was then stirred for 48 hours under a nitrogen atmosphere in a 78° C. thermostatic tank. Thereafter, the glass vessel was restored to room temperature, the inside of the glass vessel was opened to the atmosphere, and 30 g of THF was added to the resultant solution. The solution to which THF had been added was added dropwise to 300 g of methanol to cause precipitation of a polymerized product. Thereafter, the solution containing the polymerized product that had precipitated was filtered using a Kiriyama funnel to obtain a white coagulated material (polymer).

The obtained polymer 7 had a weight-average molecular weight (Mw) of 57,000 and a molecular weight distribution (Mw/Mn) of 1.88. The monomer ratio calculated through ¹H-NMR measurement was 46 mol % of α-methylstyrene units and 54 mol % of methyl α-chloroacrylate units.

Various evaluations were conducted as previously described using the polymer 7. The results are shown in Table 1. Note that diisoamyl ether (containing 2 mass % or less of di-tert-butylhydroxytoluene as an antioxidant) was used as the developer and isopropyl alcohol was used as the rinsing liquid in the various evaluations.

In the method of forming a resist pattern that included a combination of diisoamyl ether as a developer and the polymer 7 described above, sensitivity was too low, and resolution was not possible in evaluation of resolution and irradiation dose margin.

In Table 1:

“ACA1Ad” indicates 1-adamantyl α-chloroacrylate unit;

“AMS” indicates α-methylstyrene unit;

“ACA2Ad” indicates 2-adamantyl α-chloroacrylate unit;

“ACAM1Ad” indicates methyl-1-adamantyl α-chloroacrylate unit; and

“ACAM” indicates methyl α-chloroacrylate unit.

TABLE 1

| | | | Example 1 | Example 2 | Example 3 | Example 4 | Example 5 | Example 6 |
|---|---|---|---|---|---|---|---|---|
| Polymer | Type | | Polymer 1 | Polymer 1 | Polymer 2 | Polymer 3 | Polymer 4 | Polymer 4 |
| | Monomer | Yes/No | Yes | Yes | Yes | Yes | Yes | Yes |
| | unit (A) | Type | ACA1Ad | ACA1Ad | ACA1Ad | ACA1Ad | ACA2Ad | ACA2Ad |
| | Monomer | Yes/No | Yes | Yes | Yes | Yes | Yes | Yes |
| | unit (B) | Type | AMS | AMS | AMS | AMS | AMS | AMS |

| | Weight-average | 62000 | 62000 | 112000 | 69000 | 72000 | 72000 |
|---|---|---|---|---|---|---|---|
| | molecular weight [−] | | | | | | |
| | Molecular weight | 1.79 | 1.79 | 2.30 | 1.42 | 1.87 | 1.87 |
| | distrubution [−] | | | | | | |
| Developer | | Diamyl ether | Diisoamyl | Dihexyl ether | Dihexyl ether | Diamyl ether | Dihexyl ether |
| | | | ether | | | | |
| Rinsing liquid | | Heptane | Nonane | Decane | Decane | Decane | Heptane |
| Evaluation | Dry etching resistance | A | A | A | A | A | A |
| | Thickness change | A | A | A | A | A | A |
| | Sensitivity | A | A | A | A | A | A |
| | Resolution | A | A | A | A | A | A |
| | Irradiation margin | A | A | A | A | A | A |

| | | | | | Comparative | Comparative |
|---|---|---|---|---|---|---|
| | | Example 7 | Example 8 | Example 9 | Example 1 | Example 2 |
| Polymer | Type | Polymer 4 | Polymer 5 | Polymer 1 | Polymer 6 | Polymer 7 |

| | | | | | | |
|---|---|---|---|---|---|---|
| Monomer | Yes/No | Yes | Yes | Yes | Yes | No |
| unit (A) | Type | ACA2Ad | ACAM1Ad | ACA1Ad | ACA1Ad | ACAM |
| Monomer | Yes/No | Yes | Yes | Yes | Yes | Yes |
| unit (B) | Type | AMS | AMS | AMS | AMS | AMS |

| | Weight-average | 72000 | 58000 | 62000 | 15000 | 57000 |
|---|---|---|---|---|---|---|
| | molecular weight [−] | | | | | |
| | Molecular weight | 1.87 | 1.78 | 1.79 | 1.67 | 1.88 |
| | distrubution [−] | | | | | |
| Developer | | Dibutyl ether | Diisoamyl | Cyclopentyl | Diisoamyl | Diisoamyl |
| | | | ether | methyl ether | ether | ether |
| Rinsing liquid | | Decane | Decane | Decane | Heptane | Isopropyl |
| | | | | | | alcohol |
| Evaluation | Dry etching resistance | A | B | A | C | C |
| | Thickness change | A | A | D | C | A |
| | Sensitivity | A | A | Not | A | C |
| | | | | evaluable | | |
| | Resolution | A | A | Not | C | Not |
| | | | | evaluable | | evaluable |
| | Irradiation margin | B | A | Not | C | Not |
| | | | | evaluable | | evaluable |

It can be seen from Table 1 that the polymers 1 to 5 of Examples 1 to 9, which each included the monomer unit (A) and the monomer unit (B) and had a weight-average molecular weight of 30,000 or more, were able to form a resist pattern having excellent dry etching resistance compared to the polymer of Comparative Example 1, which had a weight-average molecular weight of less than 30,000, and the polymer of Comparative Example 2, which did not include the monomer unit (A).

Moreover, comparison of Examples 1 to 8 with Example 9 demonstrates that when the polymers 1 to 5, which are in accordance with the present disclosure, were developed using a developer that contained a chain dialkyl ether, a good thickness change inhibiting effect, high sensitivity and resolution, and a wide irradiation margin could be achieved.

### INDUSTRIAL APPLICABILITY

According to the present disclosure, it is possible to provide a polymer that can form a resist pattern having excellent dry etching resistance when used as a main chain scission-type positive resist.

Moreover, according to the present disclosure, it is possible to provide a positive resist composition and a method of forming a resist pattern that enable formation of a resist pattern having excellent dry etching resistance.

1. A polymer comprising:
a monomer unit (A) represented by formula (I), shown below, 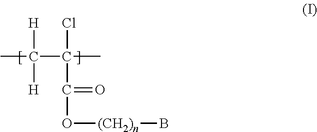
where, in formula (I), B is a bridged saturated hydrocarbon cyclic group that is optionally substituted and n is 0 or 1; and
a monomer unit (B) represented by formula (II), shown below, 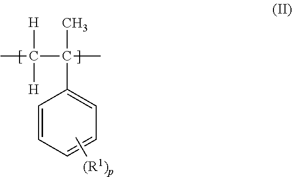
where, in formula (II), R¹ is an alkyl group and p is an integer of not less than 0 and not more than 5, and in a case in which more than one R¹ is present, each R¹ may be the same or different, wherein
the polymer has a weight-average molecular weight of 30,000 or more.

2. The polymer according to claim 1, wherein B is an optionally substituted adamantyl group.

3. A positive resist composition comprising: the polymer according to claim 1; and a solvent.

4. A method of forming a resist pattern comprising:
a step of forming a positive resist film of a main chain scission type using the positive resist composition according to claim 3;
a step of exposing the positive resist film; and
a step of developing the positive resist film that has been exposed by bringing the positive resist film into contact with a developer to obtain a developed film, wherein
the developer contains a chain dialkyl ether.

5. The method of forming a resist pattern according to claim 4, further comprising a rinsing step of rinsing the developed film by bringing the developed film into contact with a rinsing liquid after the step of developing, wherein
the rinsing liquid contains a hydrocarbon solvent.
